(19) United States
(12) Patent Application Publication
(10) Pub. No.: US 2008/0094452 A1
(43) Pub. Date: Apr. 24, 2008

(54) Inkjet Print Head

(75) Inventor: Frank W. Rohlfing, Cambridge (DE)

Correspondence Address: PHILIPS INTELLECTUAL PROPERTY & STANDARDS, P.O. BOX 3001, BRIARCLIFF MANOR, NY, 10510, US

(73) Assignee: KONINKLIJKE PHILIPS ELECTRONICS, N.V., EINDHOVEN (NL)

(21) Appl. No.: 11/722,747

(22) PCT Filed: Jan. 3, 2006
(86) PCT No.: PCT/IB06/50009

§ 371 Date: Jun. 25, 2007

(30) Foreign Application Priority Data
Jan. 6, 2005 (GB) 0500111.0

(51) Int. Cl. B41J 2/14; H01L 21/00

(52) U.S. Cl. 347/59; 438/21; 257/E21.001

(57) ABSTRACT

An inkjet print head comprising an array of print head heater circuits, each associated with a respective print head nozzle. Each heater circuit comprises a heater arrangement (12) and a drive transistor (10) for driving current through the heater arrangement (12) connected in series between power lines (V_{S}, GND). The heater arrangement (12) comprises a plurality of diode elements (16) in series. The diode elements have an inherent resistance, to provide the required heating, but the voltage drops across the diode elements enable the voltage across the transistor when in the off condition to be reduced. This enables a reduction in size of the transistor and/or enables a higher supply voltage to be used.

This invention relates to thermal inkjet printheads, particularly to the drive circuitry associated with the individual print nozzles.

Thermal inkjet printing is a printing technique that is widely used. A typical inkjet printer contains at least one print cartridge in which small droplets of ink are formed and ejected towards paper or any other print medium to form an image on the medium. The part of the cartridge that is closest to the print medium is often referred to as the print head. It contains an orifice plate into which an array of tiny nozzles is drilled. There is an ink chamber adjacent to each nozzle in which ink is stored prior to droplet formation.

Each ink chamber is equipped with a heat transducer, often in the form of an ohmic thin-film resistor. Ink ejection is accomplished by rapidly heating the ink stored in the chamber. The rapid expansion of the ink vapour forces a portion of the ink in the chamber through the nozzle in the form of a droplet. The collapsing bubble creates a vacuum in the chamber, which results in refilling of the chamber with ink from an ink reservoir within the cartridge, with which all chambers are in fluid communication. The replenished ink cools the resistor, the chamber walls and the nozzles, so that refilling and cooling prepares them for the next droplet to form when the heating resistor is next activated.

In conventional thermal inkjet print heads based on CMOS silicon wafer technology, the heat transducer is deposited in thin-film form on a silicon substrate, and the resistive material used is typically a metal alloy.

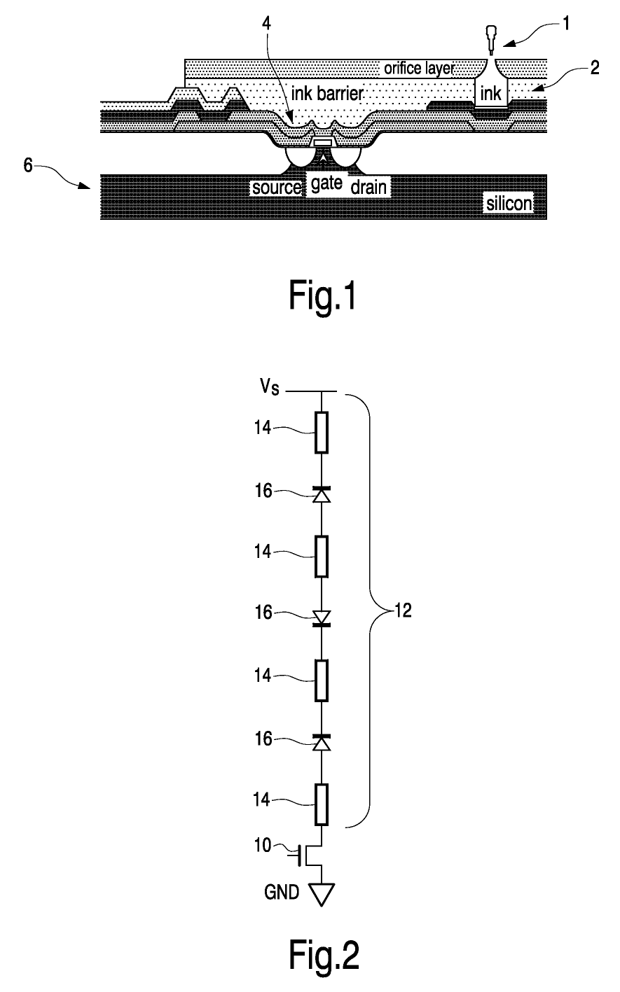

FIG. 1 shows in schematic form a first example of known print head, illustrating the nozzle 1 with a thin-film resistive heater 2 and the transistor 4 that drives it. In this example, the transistor is fabricated on a wafer 6 using a conventional silicon IC process.

In order to avoid chemical reactions between the resistive material and the ink, the heat transducer and its metal terminals are covered by at least one inert and heat resistant passivation layer, which often consists of silicon nitride. A cavitation layer may be deposited on top of the passivation layer to reduce mechanical damage to the passivation and the resistor layers, which may occur as a result of the impact from the ink that enters the chamber when it refills after droplet ejection.

One terminal of the heat transducer is connected to a supply voltage and the other terminal is connected to the drain of a drive transistor, whose source is connected to common ground. The printing data for each nozzle is made available at the transistor gate so that the heat transducer switches between on and off state in a particular sequence depending on the data to be printed. The drive transistor is adjacent to the heat transducer and it is fabricated on the same substrate as the heat transducer.

A number of different technologies can be used to form the drive transistor. The channel of the transistor has to be sufficiently wide so that its resistance in the on state is small compared to the resistance of the heat transducer. This guarantees that the external supply voltage drops almost entirely across the heat transducer in the on state, and thereby minimises energy loss in the transistor. In the off state, the supply voltage drops almost entirely across the transistor channel. It is important that the leakage current of the transistor is sufficiently low at this voltage to prevent significant temperature increases in the ink due to heat dissipation of the transistor adjacent to the ink chamber.

In order to deliver high print throughput and high print resolution, modern print heads typically have a nozzle count of several hundred and a nozzle pitch of 20-200 μm. The combination of high nozzle count and small pitch makes it impractical to address switching transistors individually with external logic circuitry, as this would require one contact pad for each nozzle. Therefore, modern print heads have logic circuitry embedded on the print head substrate, which is fabricated in the same process as the switching transistors. The integrated logic circuitry has a single, serial print data input and thereby dramatically reduces the number of external contact pads.

For advanced print heads with very high nozzle counts, poly-crystalline silicon (poly-Si) thin-film transistor (TFT) technology has been proposed.

In poly-Si print heads, poly-Si islands provide the channel, source, drain and field-relief regions. They are formed by depositing amorphous silicon (a-Si) via chemical vapour deposition (CVD) on a substrate, followed by dopant implantation and crystallisation of the a-Si with a laser or other crystallisation techniques known in this field. As the substrate is not part of the TFT but merely provides mechanical support, a wide range of substrate materials can be used such as glass, plastic foils or steel foils.

Gate oxide and gate metal are fabricated on top of the poly-Si island. Further metal layers, separated by dielectric layers, are deposited and defined photo lithographically to connect to source, drain and gate and to route signal and power lines within the print head.

The heat transducers consist of poly-Si islands as well, and in preferred process flows, the transducers are fabricated with the same process steps as the poly-Si islands for the TFTs. A low-dose region is implanted in the centre section of the poly-Si island to define the heat transducer, whilst two high dose regions define the conducting traces that connect to the transducer.

In current mass-production facilities, poly-Si technology uses large rectangular substrates with a size of 0.5-2 m². This enables the production of print heads with very wide nozzle arrays, in particular nozzle arrays whose width is equal to the width of a typical print medium (A4 or B4 paper). The key advantage of page-wide print heads is that they eliminate the need for a moving print cartridge as in current inkjet printers used for office applications. Another advantage is their increased print throughput. As conventional print heads are fabricated on silicon wafers, which are round and small, conventional technology does not permit the production of page-wide print heads.

In conventional firing chamber designs based on Si wafer CMOS technology, conducting traces are defined on top of the resistive layer to provide the two connections to the heat transducer. Hence, a conventional design has two abrupt steps within the firing chamber layers at the position where the two metal traces terminate. It is well known in the field of inkjet printing that these steps are prone to degradation due to constant temperature cycling during printing and due to the momentum caused by ink refilling the chamber after droplet ejection. In a poly-Si process, the heat transducer and its terminals are fabricated in the same poly-Si layer, resulting in a coplanar structure. This improves yield and enables the use of thinner passivation and cavitation layers, which in turn reduces the energy necessary for droplet formation.

Although the use of poly-Si technology for thermal inkjet printing is very attractive as it allows page-wide printing and improves yield in the firing chamber as outlined above, the introduction of poly-Si technology also presents a major disadvantage, and this is associated to the high on resistance of poly-Si TFTs.

The width of the firing transistors has to be very large compared to the nozzle pitch (20-200 μm). There are two key reasons for this. First, the power required for droplet formation can be as high as 2 Watts per nozzle, which means that the ON resistance has to be low to deliver a high enough current. Second, the ON resistance of the transistor should be less than 10% of the resistance of the heat transducer to ensure that the voltage drops almost entirely across the transducer.

One of the key technical issues with thermal inkjet printing is to adapt the very wide firing transistors to the small nozzle pitch. This is particularly the case for print heads in which the firing transistor is made in poly-Si technology rather than conventional CMOS technology on silicon wavers. This is because poly-Si TFTs have a higher threshold voltage, require a longer channel and have a lower mobility. They therefore deliver a lower on-current per channel width than conventional CMOS transistors. For 1 W nozzle power and 20V supply voltage applied to the heat transducer, the channel width will be of the order of a few millimetres for typical TFT parameters (channel length 4 μm, threshold voltage 2V, mobility 150 cm²/Vs and 15V gate voltage). Furthermore, in poly-Si technology, minimum feature sizes are bigger due to bigger design rules (in particular minimum spacings and contact hole sizes).

One way of reducing the required channel width is to increase the supply voltage. In order to keep the power constant, the resistance of the heat transducer has to be increased as well, and this means that a TFT with a smaller width will be sufficient to guarantee that its on-resistance is still small compared to the resistance of the heat transducer. As the resistance of the heater scales quadratically with the supply voltage for fixed power, the required transistor width reduces with the inverse of the square of the voltage. Hence, increasing the voltage is a very effective way to ensure that the transistor fits to a small nozzle pitch.

However, whilst increasing the voltage reduces the size of the TFT, it also reduces its lifetime as the higher voltage results in transistor degradation due to avalanching, hot-carrier effects and self-heating. This is particularly the case in the off state, when the full voltage drops across the TFT channel.

According to the invention, there is provided an inkjet print head comprising an array of print head heater circuits, each associated with a respective print head nozzle, wherein each heater circuit comprises a heater arrangement and a drive transistor for driving current through the heater arrangement, the heater arrangement and the drive transistor connected in series between power lines, wherein the heater arrangement comprises a plurality of diode elements in series.

The diode elements have an inherent resistance, to provide the required heating, but the voltage drops across the diode elements enable the voltage across the transistor when in the off condition to be reduced. This enables a reduction in size of the transistor and/or enables a higher supply voltage to be used.

The drive transistor preferably comprises a polysilicon thin film transistor, and the heater arrangement then comprises diodes formed from a polysilicon layer. This enables the heater to be formed from the same process steps as already required for the transistor.

The diode elements preferably comprise lateral p-n junction diodes, with the p-type and n-type junctions formed from a common polysilicon layer.

The invention also provides a method of fabricating an array of print head heater circuits for an inkjet print head, the circuits provided over a common substrate, the method comprising:

providing a dielectric layer over the common substrate;

depositing an amorphous silicon layer over the dielectric layer;

processing the amorphous silicon layer to form polycrystalline portions;

performing a plurality of doping operations to define source, gate and drain transistor regions in the polysilicon portions and to define n-type and p-type regions for p-n junction diodes;

providing a gate dielectric layer over the doped polysilicon layer;

providing a gate conductor layer over the gate dielectric layer and defining at least gate terminals from the gate conductor layer; and

providing a further dielectric layer.

The same doping process can be used to define a field relief region for the transistor as for the n-type p-n junction diode regions.

Another doping process can also be used both to define the p-type p-n junction diode regions and source and drain regions for p-type transistors of control circuitry.

These measures enable the invention to be implemented with the no or minimum additional process steps.

An example of the invention will now be described in detail with reference to the accompanying drawings, in which:

FIG. 1 shows a known print head circuit fabricated on a silicon wafer;

FIG. 2 shows a print head circuit of the invention; and

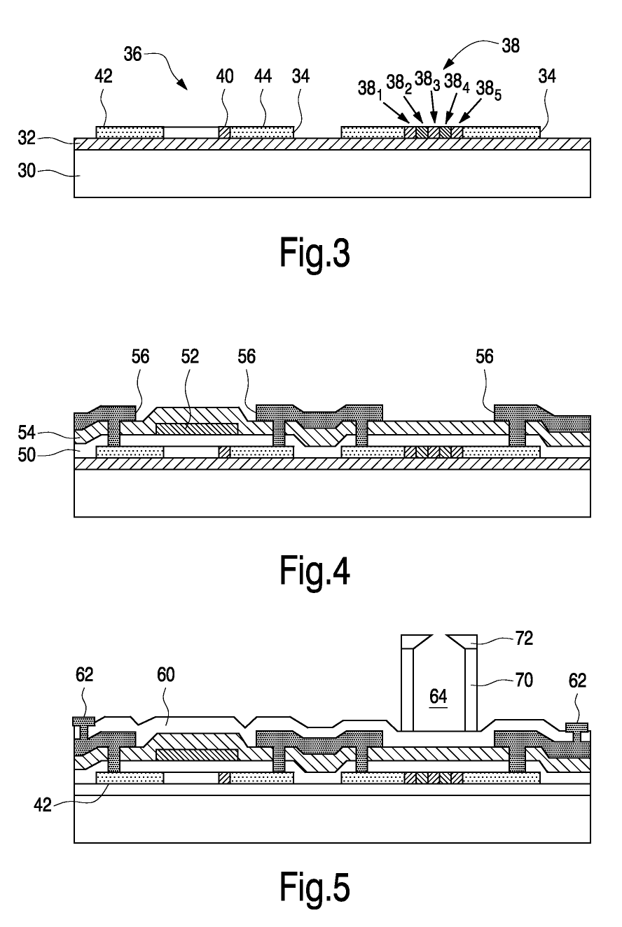

FIGS. 3 to 5 show the process used to make a print head of the invention.

FIG. 2 shows a schematic circuit diagram of an individual heater circuit of the invention.

The heater circuit comprises a thin film transistor TFT 10, and a heating arrangement 12. The invention uses a heater element in the form of plurality of diode elements 12 in series. In a preferred implementation, the series of diodes 14 operate in forward and reverse bias in alternating fashion. A resistor 16 is shown between any pair of neighboring diodes 14, and one resistor is provided at each end of the series. However, in the preferred embodiment described below, these resistors are not discrete elements, but are part of the diode characteristics.

In particular, and as will be shown in more detail below, the diodes are formed from a poly-Si island. The p and n junctions are designed such that their breakdown voltage is sufficiently low so that all reverse biased diodes operate in the breakdown region for a given supply voltage, regardless of whether the TFT 10 is in the on or in the off state. Furthermore, the implant doses and dimensions of all p and n regions are chosen such that their combined resistance is much higher than the ON-resistance of the TFT 10 (for example at least 10 times higher).

These diodes may for example be resistive, lateral thin-film diodes.

When the TFT that switches the heat transducer is in the off state, a significant fraction of the external supply voltage can then be dropped across the diode junctions, which means that the voltage across the TFT channel is reduced. Hence, this allows the use of a larger supply voltage V_{S} without compromising TFT stability. Consequently, the TFT width can be reduced, which makes it easier to design print heads with small nozzle pitches for high-resolution printers.

In a preferred implementation of the invention, the firing TFT 10 is implemented as a channel, source, drain and field-relief region defined in a poly-Si island deposited on a substrate. On top of the poly-Si island, there is a gate oxide and a gate electrode. The source is connected to common ground GND and the drain is connected to one terminal of the heater arrangement 12, which is close to and located on the same substrate as the TFT 10. The second terminal of the heat transducer is connected to the external supply voltage V_{S}. Logic circuitry (not shown) is fabricated on the same substrate to make print data available to the TFT gates.

Like the TFT, the heater arrangement 12 comprises a poly-Si island. Lateral p-n and n-p junctions are formed in this island through ion implantation using standard photolithography. The p and n regions are defined such that the poly-Si island represents a series connection of alternating pn and np diodes with one terminal of the series connected to the TFT drain and the other to the supply voltage. Each n and p region has a certain resistance, which depends on the implantation dose and the dimension of that region.

The operation of the circuit will first be described, and an example of the fabrication of the circuit using thin film processing techniques will then be given.

First, the operation of circuit in the ON state will be explained. For a high enough supply voltage V_{S} and a high injection current, the voltage drop across each diode junction extends into its p and n regions, resulting in an ohmic voltage drop across these resistive regions. The voltage drops across the junctions themselves become insignificant. The voltage drop across the resistive regions results in the desired heat dissipation to cause ink vaporisation and droplet ejection (in conventional manner).

Next, the operation of the circuit in the OFF state will be explained. When a heater in the form of a single, uniform resistive poly-Si region is used, as in a conventional design, the voltage at the drain is equal to the external supply voltage. However, in the circuit of FIG. 2, the voltage at the TFT drain is reduced by the sum of the breakdown voltages of the diodes that operate in reverse bias and an additional small amount for each diode operating in forward direction (approximately 0.2-0.7V per diode).

This breakdown voltage is typically in the range 2-10V, and the supply voltage is in the range 20-70V. The width and length of the polysilicon island for the diodes is 10 to several tens of micrometers.

Hence, the circuit of FIG. 2 enables operation at a higher supply voltage without compromising TFT degradation in the OFF state due to hot carrier degradation. A higher supply voltage means that the overall resistance of the heat transducer can be increased, which allows a reduction of the TFT channel width. As the resistance of the heat transducer scales quadratically with the supply voltage for fixed power, the required TFT width reduces with the inverse of the square of the voltage. Hence, the introduction of a diode structure into the poly-Si heat transducer island is a very effective way to ensure that the firing TFT fits to a small nozzle pitch required for high-resolution inkjet printing.

Another attractive feature of this invention is that it can be implemented without requiring any additional process steps specific to the formation of the diode structure. The poly-Si island for the heat transducer can be produced using the same process steps as those for the TFT island, and in a preferred embodiment of this invention, the process flow is optimised such that the diode heat transducer uses the same n and p implants as the TFT source, drain or field-relief regions.

FIGS. 3 to 5 show the process flow for one preferred embodiment of the invention. This embodiment is based on a non-self aligned n-type TFT architecture whose field-relief region is fully overlapped by the gate. FIGS. 3 to 5 show progressive stages in the fabrication process, and for simplicity, reference numbers for features which appear in different Figures are generally not repeated.

In a poly-Si process, the substrate 30 merely provides mechanical support for the poly-Si circuitry. Unlike conventional Si wafer processes, it does not form any part of the transistors. A range of substrates can therefore be used, like glass, plastic foils or metal foils. In poly-Si mass production processes for display applications, glass sheets with a thickness of typically 0.4 mm and a size between 0.5 and 2 m² are used.

A stack of dielectric layers 32 is deposited on the substrate, typically SiOx on top of SiNx, followed by an a-Si layer 34 with a thickness of typically 20-100 nm.

The hydrogen content of the a-Si film is reduced to typically 3% through a thermal anneal at typically 400° C. The nitride layer of the dielectric stack 32 prevents diffusion of components (e.g. Boron, Phosphorus, Na) from the substrate 30 into the deposited layers 34, in particular into the poly-Si islands that form the TFTs. Impurities in the TFT channel will affect the electrical performance of the TFT. In particular, Boron and Phosphorus will shift the threshold voltage. The preferred dual layer of SiNx and SiOx reduces the pinhole density to the substrate.

Photo resist is spun on top of the a-Si layer, into which features are defined photo lithographically to form an island 36 for the heater arrangement and an island 38 for the firing TFT. Additional n-type or p-type TFTs, resistors, capacitors, MOS capacitors or conductive traces are also defined that are required for the logic circuitry integrated on the same substrate to distribute the print data to the firing TFT gates. These additional logic circuits and the processes used to form can be conventional, and these circuits and components are not shown in the Figures.

The a-Si features can be dry etched using reactive ion etching, for example with a SF₆/HCL/O₂ gas mixture, but other etching techniques are also available to those skilled in this field.

After island definition, the TFTs need a low-dose boron implant of typically 1-3×10¹² cm⁻² to adjust their threshold voltage. However, for low levels of contamination this step may be omitted. The dopant concentration required to optimise the threshold voltage of n- and p-type TFTs may not be identical. If this is the case, a blanket implant is applied in addition to a patterned implant.

Further mask definitions and ion implantations are needed for the source, drain and field-relief regions of the firing TFTs and any n- and p-channel TFTs in the integrated logic circuitry, for the resistor and its two terminals as well as for any capacitors, MOS capacitors or conducting traces made of doped poly-Si that the logic may use.

The TFT field-relief region 40 requires a phosphorus dose between 3×10¹² and 3×10¹³ cm⁻² (typically 9×10¹² cm⁻²) to prevent TFT degradation and the source 42 and the drain 44 dose is typically 10¹⁵ cm⁻².

The same dose, but with boron as the implant species is required for the source and drain region of p-channel devices.

In a preferred embodiment of this invention, the conducting traces of the poly-Si heater arrangement and the n and p regions that form its diodes share three of the implantation steps required for the poly-Si TFTs. The advantage of this is that no additional process steps are necessary for the heat transducer, which greatly simplifies the process flow and increases production yield. Ideally, the conducting traces receive the same high-dose phosphorus implant as the source and drain of the n-type TFTs. (Alternatively, the high-dose boron implant for the p-type TFTs can be used, but the disadvantage is that the resulting sheet resistance is normally higher than the corresponding n-type implant.)

In order to produce abrupt diode junctions, a region that covers the entire diode area and that either extends into or fully includes the conducting traces is implanted as a low-dose n-type region, in the same process step as the field-relief regions 40. This defines the require doping for the n-type diode junctions.

During high-dose boron implantation for the source and drain of the p-type TFTs in the logic circuitry, regions 38₁, 38₃, and 38₅ as well as the conducting terminals of the heat transducer are covered with photo resist to produce p regions 38₂ and 38₄. During high dose phosphorus implantation for the n-type TFTs, all diodes are covered with photo resist to produce conducting traces for the heater arrangement.

There are thus three doping operations used. A low dose n-type doping is used for the field relief region in the n-type TFTs and for the n-type regions of the diodes. A high dose phosphorus doping is used for the source and drain of the n-type TFTs and for the conducting terminals of the heat transducer, and a high dose boron doping is used for the p-type regions of the diodes and for the source and drain of the p-type TFTs.

Depending on the details of the process flow and the electrical characteristics required for the TFTs and the diodes, it may not be possible that the TFTs and the heater arrangement share the same implantation steps without compromising circuit performance and print quality.

In this case, at least one additional implantation and photolithographic step can be introduced into the process. Also, for some printing applications, it may not be possible for all diodes to have identical n and p implant doses. In this case, at least one additional implant step may be introduced.

The embodiment shown schematically in FIGS. 3 to 5 uses 4 diodes, 2 in forward and 2 in reverse bias. The number of diodes connected in series depends on the details of the poly-Si process flow and the print application. The use of 4 diodes is for illustration only, and the number depends on the breakdown voltage, and preferably ranges between 2 and 10.

The number of diodes is preferably even, for two reasons. First, as the high dose phosphorus gives lower sheet resistance than the high dose boron implant, the former is the preferred implant for both conducting terminals of the heater. This requires an odd number of diode regions, corresponding to an even number of diodes. This also avoids having junctions where both implant species are high dose with similar concentrations, as this would not form a lateral diode with a suitable characteristic, and may result in process artifacts. High dose boron regions adjacent to the conducting traces would form such junctions. As shown in FIGS. 3-5, the implant adjacent the heater terminals is the low dose implant used for the field relief region 40.

After the ion implantation steps, resist removal and surface clean, the implanted a-Si islands are converted into poly-Si islands with an excimer laser beam with an energy density of typically 300 mJ/cm², or any other laser beam suitable for laser crystallisation. Alternatively, other crystallisation techniques can be used that are known in this field such as metal-induced laser crystallisation or sequential lateral solidification.

FIG. 4 shows the gate oxide 50. Its thickness may range between 20 and 150 nm and it may be deposited via CVD, following a thorough surface clean of the crystallised Si islands. The oxide also functions as a passivation layer in the firing chamber. A gate metal 52 is deposited on top of the gate oxide 50. An aluminium alloy with a typical thickness of 200 to 300 nm may be used as gate metal, and the metal can be defined using dry or wet etching. In the following step, an interlayer dielectric 54 is deposited on top of the gate metal via CVD. SiNx may be used and a typical thickness for a 200-300 nm gate metal would be 500 nm. This layer also functions as a passivation layer in the firing chamber.

Contact holes to the source and drain, the heat transducer terminals and to the gate metal are opened via wet or dry etch techniques. This requires etching through the dielectric layer 54 to connect to the gate metal, and etching through the dielectric 54 and the gate oxide 50 to connect to source, drain and resistor terminals. The connection to the gate metal is not shown in the Figures.

Depending on process details, a different technique may be needed to open contacts to the gate metal than is used to open contact windows to implanted poly-Si.

A second metal layer 56 is deposited and defined into conducting traces via photolithography and wet or dry etching.

FIG. 5 shows the dielectric layer 60 that is deposited on top of the source/drain metal 56 to allow yet another (third) metal layer 62 to be used for routing. This dielectric layer 60 also functions as a passivation and cavitation layer in the firing chamber 64. Contact holes are opened in this layer via dry or wet etch to terminate on top of the source/drain metal. The third metal layer 62 is deposited and defined photo lithographically to connect to the source 42 of the firing TFT and to one terminal of the heater arrangement. This metal is also used for higher-level routing within the integrated logic circuit.

In final process steps shown in FIG. 5, the material 70 for the firing chamber walls is deposited and the walls are defined such that the heating resistor is located inside the firing chamber. An orifice plate 72 is bonded on top of the chambers.

The embodiment shown completed in FIG. 5 is based on a non self-aligned TFT process with a single gate-overlapped field-relief region 40 at the drain. In alternative embodiments, a self-aligned process may be used with a single field-relief region or a series of field-relief regions either overlapped by or adjacent to the gate. The use of a spacer technology allows fabrication of a fully self-aligned process. For a small nozzle pitch, architectures with gate-overlapped field-relief are preferred because of their higher maximum operating voltage.

A single preferred embodiment has been described in detail above, and some possible alternative implementations have been specifically mentioned. However, the invention can be implemented in many additional way, and this will be apparent to those skilled in the art.

This invention is directed specifically to the use of diodes to form the heating arrangement. However, the particular transistor design and its use in an ink jet print head circuit also forms part of the invention, and it should not be taken from the above description that the transistor design is known.

1. An inkjet print head comprising an array of print head heater circuits, each associated with a respective print head nozzle, wherein each heater circuit comprises a heater arrangement (12) and a drive transistor (10) for driving current through the heater arrangement (12), the heater arrangement (12) and the drive transistor (10) connected in series between power lines (V_{S}, GND), wherein the heater arrangement (12) comprises a plurality of diode elements (16) in series.

2. A print head as claimed in claim 1, wherein the drive transistor (10) comprises a polysilicon thin film transistor.

3. A print head as claimed in claim 2, wherein the heater arrangement comprises diodes formed from a polysilicon layer (34).

4. A print head as claimed in claim 3, wherein the heater arrangement comprises diodes formed from the same polysilicon layer (34) as forms the source (42), drain (44) and channel of the drive transistor (10).

5. A print head as claimed in claim 1, wherein the diode elements (16) comprise lateral p-n junction diodes, with the p-type and n-type junctions formed from a common polysilicon layer (34).

6. A print head as claimed in claim 5, wherein the transistor (10) comprises a field relief doped region, and the same doping is applied to the polysilicon layer to define the field relief region (40) and the n-type regions of the diodes.

7. A print head as claimed in claim 5, wherein control circuitry is provided on the same substrate print head heater circuits comprising n-type and p-type transistors, and the same doping is applied to the polysilicon layer to define the p-type diode element terminals and for the p-type transistors of the control circuitry.

8. A print head as claimed in claim 1, wherein the drive transistors are provided over a common substrate (30) and dielectric layer stack (32) and comprise in order from the substrate:
a polysilicon layer (34);
a gate dielectric layer (50);
a gate conductor layer (52);
an interlayer dielectric layer (54); and
source and drain connections defined by a second metal layer (56).

9. A print head as claimed in claim 8, wherein each print head heater circuit comprises a heater chamber (64) above the heater arrangement, the heater chamber being provided above the polysilicon layer (34) which defines the diode elements, the gate dielectric layer (50), the interlayer dielectric layer (54) and a further dielectric layer (60).

10. A print head as claimed in claim 9, wherein the chamber (64) is defined by chamber walls (70) and an overlying orifice plate (72).

11. A print head as claimed in claim 1, wherein the diode elements are arranged in alternating polarity.

12. A print head as claimed in claim 1, wherein the combined resistance of the n-type and p-type regions of the diode series is greater than the ON resistance of the transistor.

13. A print head as claimed in claim 12, wherein the combined resistance of the n-type and p-type regions of the diode series is greater than 10 times the ON resistance of the transistor.

14. A method of fabricating an array of print head heater circuits for an inkjet print head, the circuits provided over a common substrate (30), the method comprising:
providing a dielectric layer (32) over the common substrate (30);
depositing an amorphous silicon layer over the dielectric layer (32);
processing the amorphous silicon layer to form polycrystalline portions;
performing a plurality of doping operations to define source, gate and drain transistor regions in the polysilicon portions and to define n-type and p-type regions for p-n junction diodes;
providing a gate dielectric layer (50) over the doped polysilicon layer;
providing a gate conductor layer (52) over the gate dielectric layer and defining at least gate terminals from the gate conductor layer (52); and
providing a further dielectric layer (54).

15. A method as claimed in claim 14, wherein each print head circuit is defined as a heater arrangement (12) comprising a plurality of p-n diode elements (16) in series and a drive transistor (10) for driving current through the heater arrangement (12).

16. A method as claimed in claim 14, further comprising providing a second metal layer (56) over the further dielectric layer (54) to define source and drain connections.

17. A method as claimed in claim 14, wherein performing a plurality of doping operations further defines a field relief region (40) adjacent the drain transistor region.

18. A method as claimed in claim 17, wherein the same doping process is used to define the field relief region (40) and the n-type regions of the diodes.

19. A method as claimed in claim 4, wherein control circuitry is defined on the same substrate comprising n-type and p-type transistors, and wherein the same doping process is used to define the p-type regions of the diodes and for p-type transistors of the control circuitry.

20. A method as claimed in claim 14, further comprising forming a further dielectric layer (60) and a heater chamber (64) above the further dielectric layer (60).
